(19) United States
(12) Patent Application Publication
(10) Pub. No.: US 2013/0133703 A1
(43) Pub. Date: May 30, 2013

(54) VAPORIZED MATERIAL SUPPLY APPARATUS, SUBSTRATE PROCESSING APPARATUS HAVING SAME AND VAPORIZED MATERIAL SUPPLY METHOD

(71) Applicant: Tokyo Electron Limited, Tokyo (JP)

(72) Inventor: Kazuhiro NISHIJIMA, Koshi City (JP)

(73) Assignee: TOKYO ELECTRON LIMITED, Tokyo (JP)

(21) Appl. No.: 13/686,396

(22) Filed: Nov. 27, 2012

(30) Foreign Application Priority Data
Nov. 28, 2011 (JP) 2011-259434

(51) Int. Cl. H01L 21/02

(52) U.S. Cl. CPC H01L 21/02041
USPC 134/31; 134/105; 134/108

(57) ABSTRACT

A vaporized material supply apparatus includes: a storage tank for storing a liquid material; a first temperature controller for controlling the storage tank to be at a first temperature; a carrier gas inlet line for introducing a carrier gas into the storage tank; a processing gas outlet line for discharging a processing gas out of the storage tank; a container having an inlet port connecting to the processing gas outlet line and an outlet port via which the processing gas is discharged; an interference member to interfere with flow of the processing gas in the container; and a second temperature controller for controlling the container to be at a second temperature lower than the first temperature.

### CROSS-REFERENCE TO RELATED APPLICATION

This application claims the benefit of and priority to Japanese Patent Application No. 2011-259434, filed on Nov. 28, 2011, the disclosure of which is incorporated herein in its entirety by reference.

### TECHNICAL FIELD

The present disclosure relates generally to semiconductor manufacturing of semiconductor devices, and in particular to a vaporized material supply apparatus supplying a gaseous material obtained by vaporizing liquid material, a substrate processing apparatus including the vaporized material supply apparatus, and a vaporized material supply method.

### BACKGROUND

An apparatus using gaseous material obtained by vaporizing (or volatilizing) material, e.g., a solvent or a hydrophobizing agent, which is liquid at room temperature, is used in semiconductor manufacturing apparatuses for manufacturing semiconductor devices. A well-known means for vaporizing the liquid material is, for example, a bubbler tank in which a liquid is bubbled by using a carrier gas to obtain vapor of the liquid in the carrier gas. The bubbler tank includes a tank for storing the liquid material therein, a carrier gas inlet line through which a carrier gas is introduced into the liquid material stored in the tank, and a supply line through which the carrier gas including vapor of the liquid material is supplied to a processing chamber of a semiconductor manufacturing apparatus.

In the bubbler tank, the carrier gas receives the vapor form of the liquid material as the carrier gas passes through the liquid material stored in the tank. However, if a large amount of a carrier gas, for example, flows at a high speed through the tank, the vapor form of the liquid material in the carrier gas may not be saturated. In this case, a desired amount of material cannot be supplied, which makes it difficult to control a concentration of a processing gas.

### SUMMARY

The present disclosure provides a vaporized material supply apparatus capable of improving a saturation degree of vapor of a liquid material in a carrier gas.

According to a first aspect of the present disclosure, there is provided a vaporized material supply apparatus including: a storage tank storing the liquid material therein; a first temperature controller configured to control the temperature of the storage tank to be at a first temperature; a carrier gas inlet line configured to introduce a carrier gas into the storage tank; a processing gas outlet line connected to the storage tank to discharge a processing gas out of the storage tank, wherein the carrier gas introduced into the storage tank via the carrier gas inlet line includes vapor of the liquid material to generate the processing gas; a container having an inlet port to which the processing gas outlet line is connected and an outlet port via which the processing gas introduced into the container via the inlet port is discharged out of the container; a interference member provided between the inlet port and the outlet port to interfere with flow of the processing gas in the container; and a second temperature controller configured to control the temperature of the container to be at a second temperature lower than the first temperature.

According to a second aspect of the present disclosure, there is provided a substrate processing apparatus including: a gas line configured to guide the processing gas from the outlet port of the container in the vaporized material supply apparatus of the first aspect; a chamber to which the gas line is connected and the processing gas is introduced via the gas line; and a mounting table disposed in the chamber to mount thereon a substrate to be processed by using the processing gas.

According to a third aspect of the present disclosure, there is provided a vaporized material supply method including: keeping a storage tank storing a liquid material therein at a first temperature; supplying a carrier gas into the storage tank at the first temperature to generate a processing gas containing the carrier gas and vapor of the liquid material; and cooling the processing gas to a second temperature lower than the first temperature.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 illustrates a bubbler of a vaporized material supply apparatus in accordance with some embodiments.

FIG. 2 illustrates a gas saturation unit of a vaporized material supply apparatus in accordance with some embodiments.

FIG. 3 illustrates a vaporized material supply apparatus in accordance with some other embodiments.

FIG. 4 illustrates a substrate processing apparatus in accordance with some embodiments.

### DETAILED DESCRIPTION

Hereinafter, embodiment(s) of the present disclosure will be described in detail with reference to the drawings. The embodiment(s) will be presented by way of example only, and are not intended to limit the scope of the present disclosure. The same or equal elements in the drawings are indicated by the same reference numerals, where applicable, and their descriptions are not repeated. Also, the drawings are not limited or intended to show relative ratios of the elements, but rather specific sizes of the elements can be selected by those skilled in the art in view of the following non-restrictive embodiments.

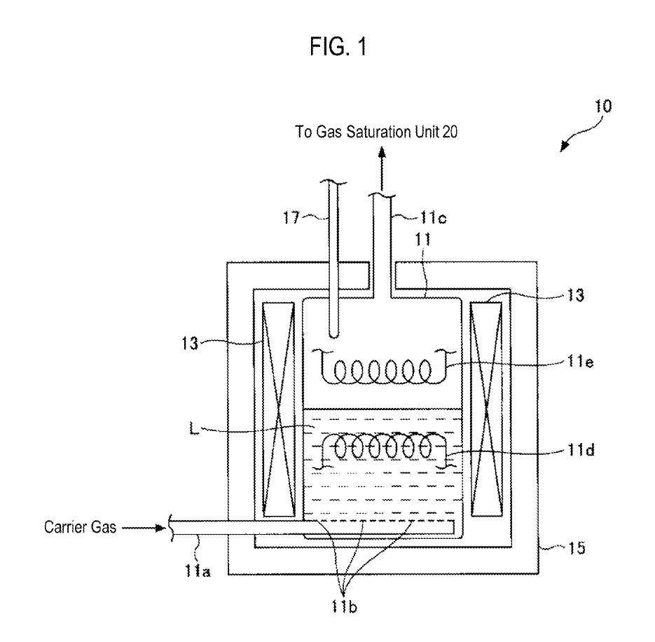

First, a bubbler tank 10 of a vaporized material supply apparatus, according to some embodiments, is described with reference to FIG. 1.

As shown in FIG. 1, the bubbler 10 includes a storage tank 11 (hereinafter, referred to as “tank”) storing source liquid material L, e.g., a solvent or a hydrophobizing agent, at room temperature, an outer heater 13 arranged around the tank 11 to heat the inside of the tank 11 and the liquid material L stored in the tank 11, and a heat insulating member 15 arranged to surround the tank 11 and the outer heater 13.

The tank 11 has a substantially cylindrical shape and is made of corrosion-resistant material, for example a metal such as stainless steel and aluminum or a resin such as polytetrafluoroethylene (PTFE), to protect from corrosion that could be caused by the liquid material L stored in the tank 11. Provided at a lower portion of the tank 11 is a carrier gas inlet line 11a, which passes through a side peripheral portion of the tank 11 and extends along an inner bottom portion of the tank 11. The carrier gas inlet line 11a is connected to a carrier gas supply source (to be described later) configured to supply a carrier gas from the carrier gas supply source to the inside of the tank 11. A portion of the carrier gas inlet line 11a located in the tank 11 includes a plurality of orifices 11b formed along a lengthwise direction of the carrier gas inlet line 11a at predetermined intervals. With this configuration, the carrier gas supplied from the carrier gas supply source is introduced into the tank 11 via the carrier gas inlet line 11a and injected into the liquid material L via the orifices 11b. The carrier gas receives a vapor form of the liquid material L while flowing, for example, upward through the liquid material L, and may also be mixed with the vapor form of the liquid material L that fills a space above the liquid material L. As a result, a processing gas formed with the carrier gas and the vapor of the liquid material L is obtained. A processing gas outlet line 11c connected to a top portion of the tank 11 allows the processing gas to be discharged outside the tank 11 via the processing gas outlet line 11c to, for example, a gas saturation unit 20 (which will be further described later).

In some embodiments, a rare gas such as helium (He) gas, argon (Ar) gas or nitrogen gas may be used as the carrier gas.

Also provided in the tank 11 may be a liquid layer heater 11d configured to heat the liquid material L, a gas layer heater 11e configured to heat the processing gas filled in the space above the liquid material L, and a temperature sensor 17 configured to measure a temperature of the processing gas. A power supply (not shown) and a temperature controller (not shown) may also be provided to each of the liquid layer heater 11d and the gas layer heater 11e, and temperatures of the liquid layer heater 11d and the gas layer heater 11e may be controlled to be at a predetermined temperature (a first temperature) based on the measurement result of the temperature sensor 17. With this configuration, the temperatures of the liquid material L and the processing gas are kept at the first temperature. The first temperature may be set based on characteristics of the liquid material L or dependent on the supply amount of the processing gas. For example, in case of using hexamethyldisilazane (HMDS) as the liquid material L, which is one of hydrophobizing agents, the first temperature may range from about 24 degree C. to about 40 degree C. In some embodiments, the first temperature may be, e.g., about 30 degree C.

The outer heater 13 is configured to surround the outer peripheral surface of the tank 11. Further, the outer heater 13 may be provided with a temperature sensor (not shown), a power supply (not shown) and a temperature controller (not shown). The outer heater 13 may also control the temperatures of the liquid material L and the processing gas in the tank 11 to be at the first temperature. With this configuration, the temperatures of the liquid material L and the processing gas in the tank 11 may easily be maintained at the first temperature. The outer heater 13 may be supplied, not only to surround the outer peripheral surface of the tank 11, but also to regions on the top and in the bottom surface of the tank 11.

The heat insulating member 15 may include, for example, fibrous glass wool or filling powder made of a low thermal conductivity material such as silica glass and a shell layer forming, for example, a textile packing material covering the silica glass. The heat insulating member 15 may further include a metal film made of, e.g., aluminum, facing the outer peripheral surface of the outer heater 13. Alternatively, the heat insulating member 15 may include a vacuum heat insulating material, in which, e.g., fabric or powder made of silica glass may be accommodated in a space between a pair of films made of a resin such as polyethylene, where the space between the pair of the films may be kept in a vacuum state.

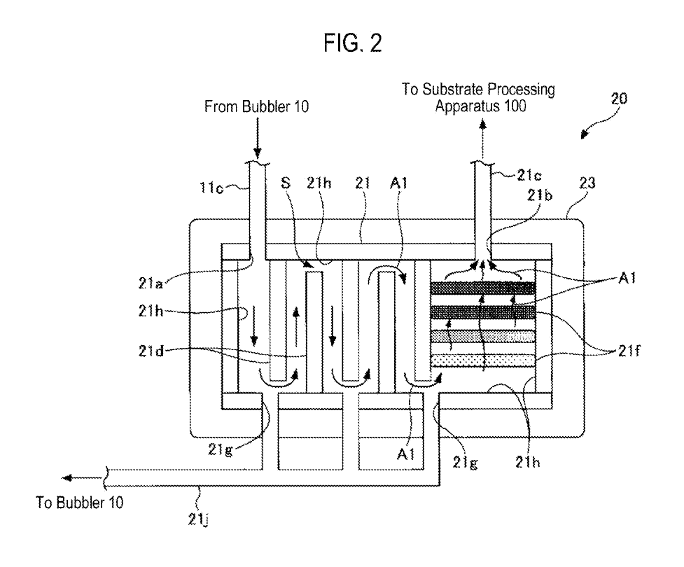

The gas saturation unit 20, which may be connected to the bubbler 10 of FIG. 1 in a vaporized material supply apparatus, is described with reference to FIG. 2, according to some embodiments.

As shown in FIG. 2, the gas saturation unit 20 includes a case (or a container) 21 and a heat insulating member 23 surrounding the case 21.

The case 21 has, for example, a substantially rectangular parallel-piped shape and may be made of metal such as stainless steel or aluminum, or a resin such as polytetrafluoroethylene (PTFE) or Perfluoroalkoxy (PFA). At one end of the upper portion of the case 21, an inlet port 21a is provided via a joint, to which the processing gas outlet line 11c from the bubbler 10 can be connected. With this configuration, the processing gas generated in the bubbler 10 is introduced into the case 21 via the processing gas outlet line 11c connected to the inlet port 21a. In addition, an outlet port 21b is provided at the other end of the upper portion of the case 21 opposite the end portion to which the inlet port 21a is provided. At the outlet port 21b, a processing gas supply line 21c is connected to a substrate processing apparatus 100 (which will be described further in detail later). With this configuration, the processing gas introduced into the case 21 via the inlet port 21a is supplied to the substrate processing apparatus 100.

Further, temperature control plates 21h may be arranged at six inner surfaces of the case 21 (four temperature control plates 21h are shown in FIG. 2). Within the temperature control plates 21h, fluid flow passages (not shown) are formed. By controlling the circulation of fluid, the temperature controller (not shown) can control the temperature to, for example, a predetermined temperature (a second temperature) between the temperature control plates 21h, and thereby maintain the temperature of the case 21 at the predetermined temperature. In some embodiments, the second temperature may be, e.g., a room temperature of 23 degree C.

Also, a plurality of baffle plates 21d (serving as an interference member) may be included in the case 21. Similarly to the temperature control plate 21h, fluid flow passages (not shown) are formed in the baffle plates 21d and the temperature of the baffle plates 21d is controlled by circulation of temperature-controlled fluid in the fluid flow passages. In some embodiments, the temperature of the baffle plates 21d may be equal to that of the temperature control plates 21h, e.g., a room temperature of 23 degree C. In some embodiments, for example as shown in FIG. 2, each of the baffle plates 21d has a flat rectangular parallel-piped shape. Among the four-sided surfaces of the flat rectangular parallel-piped shaped baffle plate, one side surface is spaced apart from the temperature control plates 21h while the three side surfaces are in contact with three corresponding temperature control plates 21h. By spacing apart one side surface of each of the baffle plates 21d from the temperature control plates 21h, a gas flow passage S is formed between the baffle plates 21d and the temperature control plates 21h.

The baffle plates 21d are arranged such that a first baffle plate 21d neighboring to a second baffle plate 21d, which is spaced apart from a first temperature control plate 21h, is spaced apart from a second temperature control plate 21h facing the first temperature control plate 21h. With this configuration, gas flow passages S are alternately arranged to form a long labyrinthine gas flow passage. Accordingly, the processing gas introduced into the case 21 via the inlet port 21a flows toward the outlet port 21b while the flow direction of the processing gas is changed by multiple times as indicated by arrow A1. With this configuration, the processing gas is cooled from the first temperature to the second temperature and then kept at the second temperature.

The baffle plates 21d are provided across a region between temperature control plates 21h in the case 21 and one or more filters 21f are provided at a space between the region and the outlet port 21b. The filters 21f extend along a direction across a flow direction of the processing gas within the case 21. From this, the processing gas passes through the filters 21f to reach the outlet port 21b. The opening sizes of the filters 21f may be determined based on characteristics of the liquid material L, e.g., viscosity of the liquid material L, stored in the tank 11. In the embodiment shown in FIG. 2, four filters 21f having different opening sizes are provided. To be specific, the four filters 21f are arranged so that the opening sizes decrease towards the downstream side in the flow direction of the processing gas. In some embodiments, the filters 21f may be made of polyethylene or PTFE. Alternatively, the filters 21f may be made of a high thermal conductivity material such as stainless steel or aluminum, and in this case, for example, temperatures of the filters 21f may be controlled to be equal to the temperature of the temperature control plates 21h or the baffle plates 21d.

In addition, one or more liquid ports 21g may be formed at the bottom portion of the case 21 and the liquid ports 21g may be connected to a return line 21j. More particularly, the liquid ports 21g may be arranged between two adjacent baffle plates 21d which are in contact with the temperature control plate 21h disposed at the bottom portion of the case 21. With this configuration, the liquid material L stored between the two adjacent baffle plates 21d can be discharged to the return line 21j via the liquid port 21g. Since the return line 21j is connected to the tank 11 of the bubbler 10, the liquid material L stored in the case 21 of the gas saturation unit 20 can return to the tank 11 of the bubbler 10.

The heat insulating member 23 surrounding the case 21 is configured to be the same as the heat insulating member 15 of the tank 11.

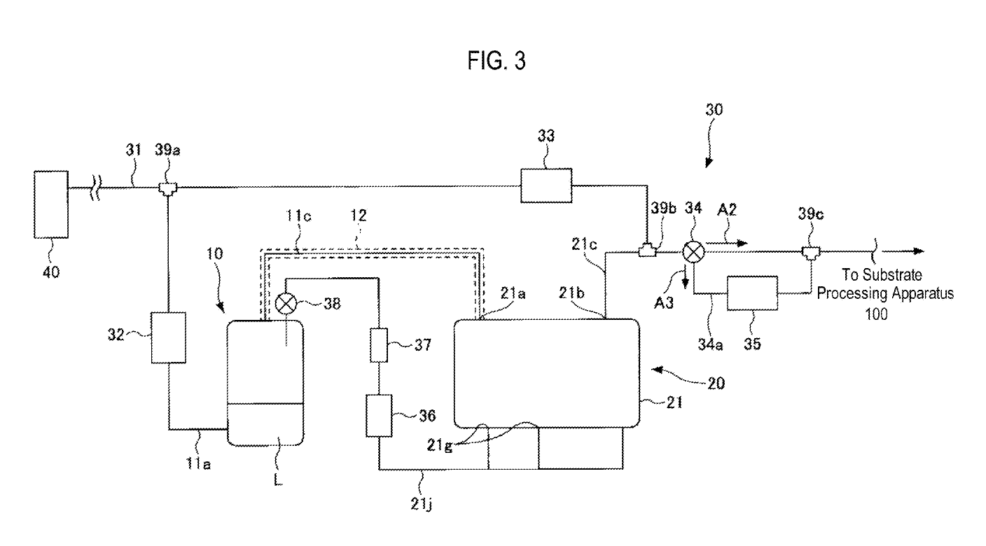

Hereinafter, a vaporized material supply apparatus 30, which includes the above-described bubbler 10 and the gas saturation unit 20, according to the embodiment of the present disclosure are further described with reference to FIG. 3. In FIG. 3, the bubbler 10 and the gas saturation unit 20 are shown as blocks.

As shown in FIG. 3, the vaporized material supply apparatus 30 includes, in addition to the above-described bubbler 10 and the gas saturation unit 20 a line 31 connected to a carrier gas supply source 40 and a flow rate controller 32 disposed in the carrier gas inlet line 11a, which extends from the line 31 by a joint 39a, to control a flow rate of the carrier gas. The line 31 joins the processing gas supply line 21c via a joint 39b, and a flow rate controller 33 configured to control a flow rate of the carrier gas flowing the line 31 is disposed between the joints 39a and 39b. The flow rate controllers 32 and 33 may be, e.g., mass flow controllers.

In the embodiment shown in FIG. 3, a three-way valve 34 is disposed at the downstream side of the joint 39b in the processing gas supply line 21c. The three-way valve 34 is connected to a bypass line 34a and the bypass line 34a joins the processing gas supply line 21c at the downstream side of the three-way valve 34 via a joint 39c. In normal time, through the three-way valve 34, the processing gas in the processing gas supply line 21c flows to the processing gas supply line 21c as indicated by arrow A2. However, when the three-way valve 34 is switched, the processing gas flows through the three-way valve 34 to the bypass line 34a indicated as arrow A3. In the bypass line 34a, a flowmeter 35 is provided to measure a flow rate of the processing gas flowing in the bypass line 34a. The flowmeter 35 may be a mass flow meter or a float type flow meter.

In addition, a heat insulating member 12 is provided at the processing gas outlet line 11c connecting the bubbler 10 and the gas saturation unit 20. With this configuration, the temperature of the processing gas outlet line 11c can be maintained at the same temperature as the processing gas generated in the bubbler 10. Accordingly, vapor of the liquid material L in the processing gas flowing in the processing gas outlet line 11c is prevented from condensing in the processing gas outlet line 11c, and as such clogging of the processing gas outlet line 11c by the liquid material L is avoided.

As described above, the return line 21j is connected to the liquid port 21g formed at the bottom portion of the case 21 of the gas saturation unit 20. The return line 21j is also connected to the upper portion of the bubbler 10, and includes a pump 36, a filter 37 and an opening/closing valve 38. The liquid material L stored in the bottom portion of the case 21 of the gas saturation unit 20 can flow back from the case 21 to the tank 11 when the opening/closing valve 38 is open and the pump 36 is operated.

Operation of the vaporized material supply apparatus 30 configured as described above is described. The carrier gas supplied from the carrier gas supply source 40 flows to the carrier gas inlet line 11a via the line 31 and introduced into the bubbler 10 while the flow rate of the carrier gas is controlled by the flow rate controller 32 disposed in the carrier gas inlet line 11a. As described above with reference to FIG. 1, the carrier gas is injected into the liquid material L via the orifices 11b formed in the carrier gas inlet line 11a and passes through the liquid material L to reach the space above the liquid material L. During this process, the liquid material L is kept at the first temperature by the outer heater 13, the liquid layer heater 11d, the gas layer heater 11e and the temperature sensor 17 of the bubbler 10. Accordingly, vapor form of the liquid material L is included in the carrier gas with a vapor pressure determined at the first temperature and the processing gas, which includes the carrier gas and the vapor (or a gas) of the liquid material L, is generated. The generated processing gas is introduced into the gas saturation unit 20 via the processing gas outlet line 11c.

In the gas saturation unit 20, the temperature control plates 21h and the baffle plates 21d are maintained at the second temperature (e.g., a room temperature of 23 degree C.), which is lower than the first temperature. Thus, the processing gas introduced into the case 21 is cooled to the second temperature by making contact with the temperature control plates 21h or the baffle plates 21d several times as the processing gas flows through the gas flow passage S formed by the configuration of the temperature control plates 21h and the baffle plates 21d. With this configuration, a saturation degree of the vapor of the liquid material L in the processing gas can be increased.

The processing gas having an increased saturation degree of the vapor form of the liquid material L flows out of the region where the baffle plates 21d are provided and reaches the filters 21f. While the processing gas passes through the filters 21f, a mist due to condensation generated from cooling the processing gas to the second temperature is removed. After passing through the filters 21f, the processing gas is discharged to the processing gas supply line 21c via the outlet port 21b and then supplied to the substrate processing apparatus 100 (to be described later) via the processing gas supply line 21c.

As described above, with respect to the vaporized material supply apparatus 30 of FIG. 3, the processing gas containing the carrier gas and the vapor of the liquid material L maintained at the first temperature is generated in the bubbler 10 and then cooled to the second temperature that is lower than the first temperature in the gas saturation unit 20, thereby supplying a processing gas having an increased saturation degree of the vapor of the liquid material L to the substrate processing apparatus 100. Further, if the first and the second temperatures are set such that the vapor pressure of the liquid material L in the processing gas becomes the saturated vapor pressure, the vapor of the liquid material L in the processing gas can be condensed in the case 21 and saturated until the vapor pressure reaches almost the saturation vapor pressure.

In particular, if the second temperature is controlled such that the vapor pressure of the liquid material L in the processing gas becomes the saturated vapor pressure, the liquid material L is condensed on the baffle plates 21d or the temperature control plates 21h in the case 21. Further, the condensed liquid material L can flow along the baffle plates 21d or the temperature control plates 21h to be collected and stored at the bottom portion of the case 21. The liquid material L stored at the bottom portion of the case 21 flows back to the tank 11 by opening the opening/closing valve 38 provided in the return line 21j and operating the pump 36. Accordingly, the liquid material L can be recycled and prevented from being wasted, thereby reducing the substrate processing cost in the substrate processing apparatus 100.

During the flowing back of the liquid material L to the tank 11, even if particles are contained in the liquid material L stored in the case 21, the particles may be removed by the filter 37 and thus cleaned liquid material L returns to the tank 11 of the bubbler 10.

In addition, the processing gas from the gas saturation unit 20 may be diluted by supplying the carrier gas to the processing gas supply line 21c via the line 31 joining the processing gas supply line 21c by the joint 39b. In some embodiments, the processing gas diluted by the carrier gas from the line 31 may be appropriately bypassed to the bypass line 34a by opening the three-way valve 34 while the flow rate of the carrier gas can be controlled by the flow rate controller 33 provided in the line 31. With this configuration, the flow rate of the processing gas from the gas saturation unit 20 can be obtained based on a flow rate measured by the flowmeter 35 of the bypass line 34a and a flow rate of the carrier gas can be controlled by the flow rate controller 33 in the line 31 (the flow rate of the processing gas from the gas saturation unit 20 can be obtained by subtracting a flow rate set by the flow rate controller 33 from the flow rate measured by the flowmeter 35). Further, if the vapor of the liquid material L in the processing gas is saturated in the gas saturation unit 20, the concentration of the vapor of the liquid material L in the diluted processing gas can be obtained, which allows for an improvement in the supply amount accuracy of the vapor of the liquid material L to the substrate processing apparatus 100. The concentration of the vapor of the liquid material L in the processing gas can be controlled by the flow rate controller 33.

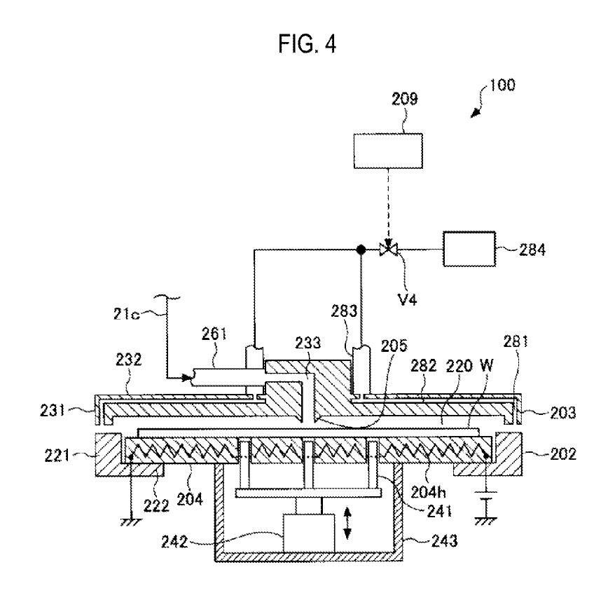

Hereinafter, the substrate processing apparatus 100, which uses the vaporized material supply apparatus 30, according to some embodiments, is described with reference to FIG. 4.

Referring to FIG. 4, the substrate processing apparatus 100 includes a container body 202 having an opening at the upper end thereof and a lid 203 covering the opening. The container body 202 includes a frame 221 having a ring shape when viewed from the top, a flange 222 extending inwardly from a bottom portion of the frame 221, and a mounting table 204 supported by the flange 222. A heater 204h is provided in the mounting table 204 and thus a wafer W mounted on the mounting table 204 can be heated.

The lid 203 covers the container body 202 such that a peripheral portion 231 of the lid 203 is disposed in close vicinity of the top surface of the frame 221 of the container body 202 and a processing chamber 220 is defined between the container body 202 and the lid 203.

In the mounting table 204, a plurality of elevating pins 241 configured to perform a transfer of the wafer W with an external transfer apparatus (not shown) is provided. The elevating pins 241 are vertically movable by an elevating mechanism 242. Reference numeral 243 in FIG. 4 denotes a cover provided at the rear side of the mounting table 204 to cover the elevating mechanism 242. The container body 202 and the lid 203 are configured to be relatively vertically movable. In the embodiment shown in FIG. 4, the lid 203 can vertically move between a processing position, where the lid 203 is brought into contact with the container body 202, and a substrate transfer position disposed above the container body 202 by an elevating mechanism (not shown).

At a central portion in the rear side of the lid 203, a processing gas supply unit 205 configured to supply a processing gas to the wafer W mounted on the mounting table 204 is provided. Further, a gas supply path 233 communicating with the processing gas supply unit 205 is formed inside the lid 203. In the embodiment shown in FIG. 4, the gas supply path 233 is bent at an inner upper portion of the lid 203 and extends horizontally therefrom so that the upstream-side end of the gas supply path 233 is connected to a gas supply pipe 261. The upstream-side end of the gas supply pipe 261 is connected to the gas saturation unit 20 of the vaporized material supply apparatus 30 via the processing gas supply line 21c. The processing gas supply unit 205, the gas supply path 233 and the gas supply pipe 261 together form a gas line guiding the processing gas generated in the vaporized material supply apparatus 30. With this configuration, the processing gas containing the carrier gas and the vapor of the liquid material L is supplied from the vaporized material supply apparatus 30 to the processing chamber 220 of the substrate processing apparatus 100, thereby exposing the wafer W mounted on the mounting table 204 to the processing gas.

In addition, a gas exhaust path 281 configured to gas-exhaust the inside of the processing chamber 220 from a radially outer position than the wafer W mounted on the mounting table 204 is formed in the lid 203. Further, a cavity 282 extending planarly in a region other than the central portion where the processing gas supply unit 205 is disposed is formed inside a ceiling portion 232 of the lid 203. The cavity 282 is shaped as a planar ring, for example. The downstream-side end of the gas exhaust path 281 is connected to the cavity 282. Further, a plurality of, for example, six, gas exhaust lines 283 may be connected to the cavity 282 at a region in the vicinity of the central portion of the lid 203, for example. The downstream-side ends of the gas exhaust lines 283 are connected to a gas exhaust mechanism (ejector) 284 via an exhaust amount control valve V4. Opening/closing of the exhaust amount control valve V4 is controlled by a valve controller 209.

With this configuration, the processing gas is supplied from the vaporized material supply apparatus 30 to the wafer W mounted on the mounting table 204 via the processing gas supply line 21c, the gas supply pipe 261, the gas supply path 233 and the processing gas supply unit 205, and is discharged by the gas exhaust mechanism 284 via the gas exhaust path 281, the cavity 282 and the gas exhaust lines 283.

Since the vaporized material supply apparatus 30 is connected to the substrate processing apparatus 100, the above-described advantageous effect of the vaporized material supply apparatus 30 can still be provided when using the substrate processing apparatus 100.

Though described with reference to the embodiments, the present disclosure is not limited to the above-described embodiments and various changes, combinations, or modification can be made within the scope of the present disclosure.

For example, though the carrier gas inlet line 11a passes through the side peripheral portion of the tank 11 and extends along the inner bottom portion of the tank 11 in one or more of the above-described embodiments, the carrier gas inlet line 11a may pass through the upper portion (a lid portion) of the tank 11 and extend to the liquid material L stored in the tank 11 (in some other embodiments, to the vicinity of the bottom surface of the liquid material L).

Further, the liquid layer heater 11d and the gas layer heater 11e are not limited to heating wires made of a nickel-chrome alloy, a steel-nickel-chrome alloy or steel-chrome-aluminum alloy, and may be sheath heaters or ceramic heaters, for example, which have excellent chemical resistances.

In the above-described embodiments, HMDS is presented as an example of the liquid material L stored in the tank 11. However, liquid material such as other hydrophobizing agent, a developing solution, a rinse (thinner), pure water or oxygenated water may be selected depending on the substrate processing type and stored in the tank 11 to thereby supply a processing gas containing vapor (or gas) of the liquid material and a carrier gas to the substrate processing apparatus 100.

Though the outer heater 13 and the heat insulating member 15 are provide in the tank 11 in the above-described embodiments, a thermostat bath may be used instead. Also, the temperature control plates 21h and the heat insulating member 23 of the gas saturation unit 20 may be replaced with a thermostat bath. In this case, the baffle plate 21d need not be temperature-controllable. When not using the temperature control plates 21h, gaps may be generated between the inner surfaces of the case 21 and the baffle plates 21d and a gas flow passage can be formed along the gaps.

Further, a heater may be provided to the processing gas outlet line 11c connecting the bubbler 10 and the gas saturation unit 20 by winding a flexible heater such as a tape heater or a ribbon heater around the processing gas outlet line 11c, instead of or in addition to the heat insulating member 12. The processing gas outlet line 11c can be maintained at a predetermined temperature by temperature-controlling the heater by using a power supply, a temperature sensor and a temperature controller. In some embodiments, the predetermined temperature may be equal to or higher than the above-described first temperature, for example.

In the above-described embodiments, the temperature of the gas saturation unit 20 is at room temperature. However, the gas saturation unit 20 may be controlled to be at a temperature higher than the room temperature. In this case, the temperature of the processing gas in the tank 11 and the temperature of the processing gas outlet line 11c may need to be higher than the temperature of the gas saturation unit 20. Further, when the gas saturation unit 20 is maintained at a temperature higher than room temperature, the temperature of the processing gas supply line 21c connecting the gas saturation unit 20 and the substrate processing apparatus 100 may be controlled to be equal to or higher than the temperature of the gas saturation unit 20 (the second temperature).

In the above-described embodiments, the pump 36 is provided in the return line 21j connecting the case 21 of the gas saturation unit 20 and the tank 11 and the liquid material L stored in the bottom portion of the case 21 flows back to the tank 11 by the pump 35. However, if the gas saturation unit 20 is positioned higher than the tank 11, the liquid material L stored in the bottom portion of the case 21 may return to the tank 11 by self-weight. In this case, the liquid material L can return to the tank 11 by opening the opening/closing valve 38 without using the pump 35.

Instead of the top portion of the tank 11, the return line 21j may be connected to a side surface of the tank 11.

In some embodiments, a liquid-level meter (not shown) may be provided in the case 21 of the gas saturation unit 20 to monitor the amount of the liquid material L stored in the bottom portion of the case 21. In this case, the liquid material L stored in the case 21 can automatically return to the tank 11 by controlling the start of the opening/closing valve 38 or the pump 36 based on the measurement result of the liquid-level meter.

In some embodiments, each of the baffle plates 21d provided in the gas saturation unit 20 may have a predetermined size of opening and four sides in contact with the inner surfaces of the case 21 (or the temperature control plates 21h). In this case, the baffle plates 21d may be arranged such that the openings are not in parallel with a flow direction of the processing gas in the case 21 (such that the openings cross the flow direction). With this configuration, the processing gas can be cooled by colliding with the baffle plates 21d (portions in the baffle plates 21d other than the openings). In some embodiments, the baffle plates 21d may be made of a porous material so that the processing gas passes through the pores. That is, the filters 21f may be used as the baffle plates 21d. Instead of the baffle plates 21d, a temperature-controllable bendable tube bent at a plurality of places to form a gas flow passage in a labyrinth shape may be used.

Further, mist traps may be provided in the gas saturation unit 20 instead of the filters 21f.

In some embodiments, a heater may be provided in the return line 21j to control the temperature of the return line 21j to be at the first temperature. With this configuration, temperature changes of the liquid material L in the tank 11 of the bubbler 10, which may follow the flowing back of the liquid material L, can be suppressed.

According to the embodiments of the present disclosure, it is possible to improve a saturation degree of vapor of a liquid material in a carrier gas.

While certain embodiments have been described, these embodiments have been presented by way of example only, and are not intended to limit the scope of the present disclosure. Indeed, the novel methods and apparatuses described herein may be embodied in a variety of other forms or combinations; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A vaporized material supply apparatus, comprising:
a storage tank configured to store a liquid material therein;
a first temperature controller configured to control the storage tank to be at a first temperature;
a carrier gas inlet line configured to introduce a carrier gas into the storage tank;
a processing gas outlet line connected to the storage tank configured to discharge a processing gas from the storage tank, wherein the carrier gas introduced into the storage tank via the carrier gas inlet line includes vapor of the liquid material to generate the processing gas;
a container having an inlet port configured to receive the processing gas and to which the processing gas outlet line is connected and an outlet port configured to discharge the processing gas in the container;
an interference member provided between the inlet port and the outlet port of the container, configured to interfere with a flow of the processing gas in the container; and
a second temperature controller configured to control the container to be at a second temperature lower than the first temperature.

2. The vaporized material supply apparatus of claim 1, further comprising:
a processing gas supply line connected to the outlet port; and
a carrier gas supply line connected to the processing gas supply line configured to supply the carrier gas to the processing gas supply line.

3. The vaporized material supply apparatus of claim 2, wherein the container includes one or more filters disposed between the interference member and the outlet port such that the processing gas flows through the filters.

4. The vaporized material supply apparatus of claim 1, further comprising:
a processing gas supply line connected to the outlet port;
a bypass line branched from the processing gas supply line and connected to the processing gas supply line; and
a flowmeter provided in the bypass line.

5. The vaporized material supply apparatus of claim 4, wherein the container includes one or more filters disposed between the interference member and the outlet port such that the processing gas flows through the filters.

6. The vaporized material supply apparatus of claim 4, further comprising:
a return line connecting the container and the storage tank, configured to control the flow of the liquid material condensed in the container to the storage tank.

7. The vaporized material supply apparatus of claim 4, further comprising:
a third temperature controller configured to control the processing gas outlet line to be at the first temperature.

8. The vaporized material supply apparatus of claim 1, wherein the container includes one or more filters disposed between the interference member and the outlet port such that the processing gas to flows through the filters.

9. The vaporized material supply apparatus of claim 8, further comprising:
a return line connecting the container and the storage tank, configured to control the flow of the liquid material condensed in the container to the storage tank.

10. The vaporized material supply apparatus of claim 8, further comprising:
a third temperature controller configured to control the processing gas outlet line to be at the first temperature.

11. The vaporized material supply apparatus of claim 1, further comprising:
a return line connecting the container and the storage tank, configured to control the flow of the liquid material condensed in the container to the storage tank.

12. The vaporized material supply apparatus of claim 11, further comprising:
a third temperature controller configured to control the processing gas outlet line to be at the first temperature.

13. The vaporized material supply apparatus of claim 1, further comprising:
a third temperature controller configured to control the processing gas outlet line to be at the first temperature.

14. A substrate processing apparatus, comprising:
a gas line configured to guide the processing gas from the outlet port of the container in the vaporized material supply apparatus of claim 1;
a chamber to which the gas line is connected and the processing gas is introduced via the gas line; and
a mounting table disposed in the chamber to mount thereon a substrate to be processed and exposed to the processing gas.

15. A vaporized material supply method, comprising:
maintaining a storage tank having a liquid material at a first temperature;
supplying a carrier gas into the storage tank at the first temperature;
in response to supplying the carrier gas at the first temperature, generating a processing gas including the carrier gas and vapor of the liquid material; and
cooling the processing gas to a second temperature lower than the first temperature.

16. The vaporized material supply method of claim 15, wherein the cooling the processing gas includes adding the carrier gas to the processing gas cooled to the second temperature.

17. The vaporized material supply method of claim 16, wherein the adding the carrier gas to the processing gas includes obtaining a flow rate of the processing gas before adding the carrier gas thereto based on a flow rate of the carrier gas and a flow rate of the processing gas after adding the carrier gas thereto.

18. The vaporized material supply method of claim 17, wherein the cooling the processing gas includes controlling the flow of the liquid material, condensed by cooling the processing gas, back to the tank.

19. The vaporized material supply method of claim 16, wherein the cooling the processing gas includes controlling the flow of the liquid material, condensed by cooling the processing gas, back to the tank.

20. The vaporized material supply method of claim 15, wherein the cooling the processing gas includes controlling the flow of the liquid material, condensed by cooling the processing gas, back to the tank.
